(19) United States
(12) Patent Application Publication
(10) Pub. No.: US 2025/0379082 A1
(43) Pub. Date: Dec. 11, 2025

(54) SEPARATION SYSTEM AND SEPARATION METHOD

(71) Applicant: Tokyo Electron Limited, Tokyo (JP)

(72) Inventor: Katsuhiro IINO, Koshi City (JP)

(73) Assignee: Tokyo Electron Limited, Tokyo (JP)

(21) Appl. No.: 19/228,689

(22) Filed: Jun. 4, 2025

(30) Foreign Application Priority Data
Jun. 5, 2024 (JP) 2024-091605

(51) Int. Cl. H01L 21/677; H01L 21/67; H01L 21/683

(52) U.S. Cl. CPC H01L 21/67742; H01L 21/6704; H01L 21/6836

(57) ABSTRACT

A separation system separates a combined substrate, in which a first substrate and a second substrate are bonded to each other, into the first substrate and the second substrate. The separation system includes a carry-in/out station in which the combined substrate and the separated first and second substrates are accommodated in a standby state; and a processing station which is equipped with at least one of a separation device that separates the combined substrate into the first substrate and the second substrate and a pre-processing device that reduces a bonding strength between the first substrate and the second substrate. The carry-in/out station is internally equipped with a first transfer device that transfers the combined substrate, the separated first substrate and the separated second substrate, and the processing station is internally equipped with a second transfer device that transfers the combined substrate, the separated first substrate and the separated second substrate.

### CROSS-REFERENCE TO RELATED APPLICATION

This application claims the benefit of Japanese Patent Application No. 2024-091605 filed on Jun. 5, 2024, the entire disclosures of which are incorporated herein by reference.

### TECHNICAL FIELD

The exemplary embodiments described herein pertain generally to a separation system and a separation method.

### BACKGROUND

Patent Document 1 discloses a separation system (semiconductor manufacturing system) that separates a combined substrate, which is held by a holding jig equipped with a dicing frame and a dicing tape, into a target substrate (frame-attached substrate) and a support substrate.

In the separation system, the frame-attached combined substrate in which the combined substrate is held by the holding jig is transferred into a separation station by a first transfer device of a first processing block transfers, and a separation processing is performed in the separation station. Also, in the separation system, the separated frame-attached substrate is transferred into a first cleaning station by the first transfer device, and cleaning is performed in the first cleaning station. Then, the cleaned frame-attached substrate is transferred into a carry-in/out station by the first transfer device. Further, in the separation system, the separated support substrate is transferred into a second cleaning station of a second processing block by a third transfer device, and the cleaned support substrate is transferred by a second transfer device.

### PRIOR ART DOCUMENT

Patent Document 1: Japanese Patent Laid-open Publication No. 2014-053463

### SUMMARY

In one exemplary embodiment, a separation system configured to separate a combined substrate, in which a first substrate and a second substrate are bonded to each other, into the first substrate and the second substrate, includes: a carry-in/out station in which the combined substrate and the separated first and second substrates are accommodated in a standby state; and a processing station which is equipped with at least one of a separation device configured to separate the combined substrate into the first substrate and the second substrate and a pre-processing device configured to reduce a bonding strength between the first substrate and the second substrate of the combined substrate. The carry-in/out station is internally equipped with a first transfer device configured to transfer the combined substrate, the separated first substrate and the separated second substrate, and the processing station is internally equipped with a second transfer device configured to transfer the combined substrate, the separated first substrate and the separated second substrate.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a plan view illustrating a separation system according to an exemplary embodiment;

FIG. 2 is a longitudinal cross-sectional view of the separation system of FIG. 1 at an intermediate position in a Y-axis direction;

FIG. 3A is a longitudinal cross-sectional view of a frame-attached combined wafer, and

FIG. 3B is a plan view of the frame-attached combined wafer;

FIG. 4 is a longitudinal cross-sectional view schematically illustrating a pre-processing device of the separation system;

FIG. 5 is a longitudinal cross-sectional view schematically illustrating a separation device of the separation system;

FIG. 6 is a perspective view illustrating a first transfer device of the separation system;

FIG. 7 is a perspective view illustrating a transfer device of the separation system;

FIG. 8A is a perspective view illustrating an end effector that supports an upper wafer, and

FIG. 8B is a side view schematically illustrating the end effector that supports the upper wafer;

FIG. 9A is a perspective view illustrating an end effector that supports the frame-attached combined wafer, and

FIG. 9B is a side view schematically illustrating the end effector that supports the frame-attached combined wafer;

FIG. 10A is a perspective view illustrating an end effector and a substrate end effector, and

FIG. 10B is a side view schematically illustrating a state where the end effector and the substrate end effector are applied;

FIG. 11 is a flowchart illustrating a separation method including a transfer method;

FIG. 12 is a plan view illustrating a separation system according to a first modification example;

FIG. 13 is a plan view illustrating a separation system according to a second modification example; and

FIG. 14 is a plan view illustrating a separation system according to a third modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, same parts will be assigned same reference numerals, and redundant description will be omitted. Further, the X-axis direction, the Y-axis direction, and the Z-axis direction used in the following description are axis directions perpendicular to each other. The X-axis direction and the Y-axis direction are horizontal directions, and the Z-axis direction is a vertical direction.

### <Configuration of Separation System 100>

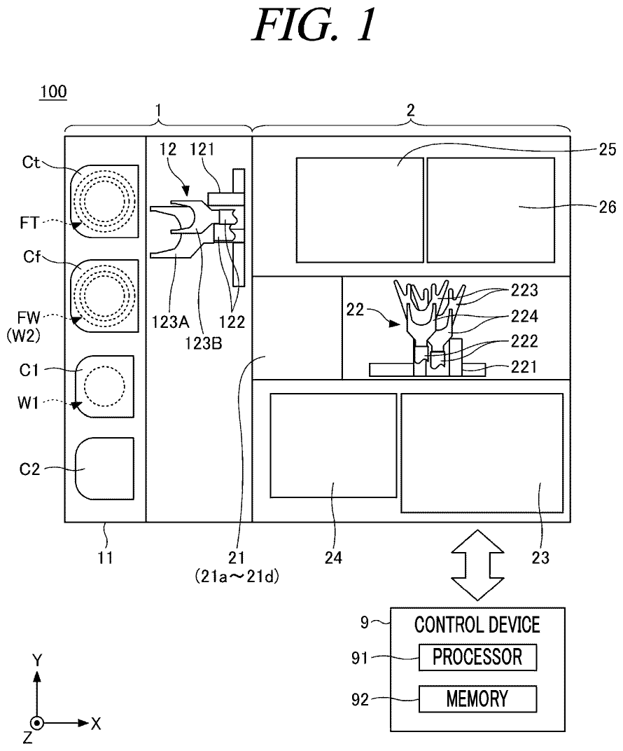

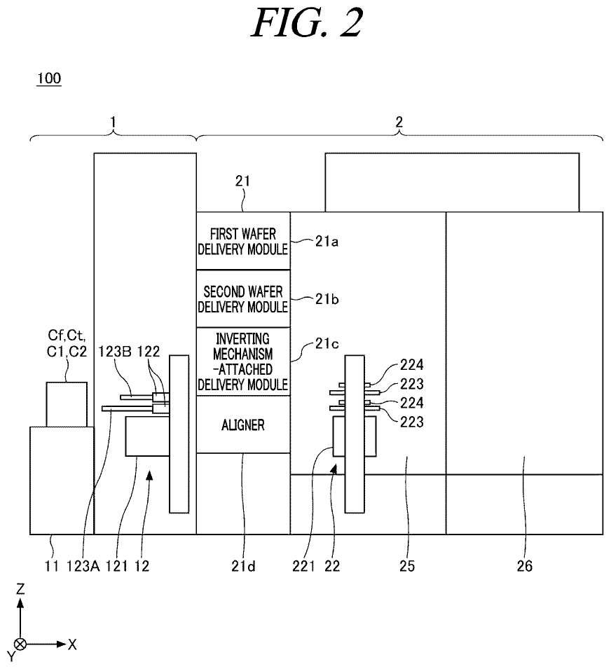

A separation system 100 according to an exemplary embodiment of the present disclosure is an example of a semiconductor manufacturing system that transfers a substrate therein and performs one or more processings on the substrate, as shown in FIG. 1 and FIG. 2. More specifically, the separation system 100 performs a separation processing to separate a combined substrate T, in which a first substrate W1 and a second substrate W2 are bonded to each other, into the first substrate W1 and the second substrate W2.

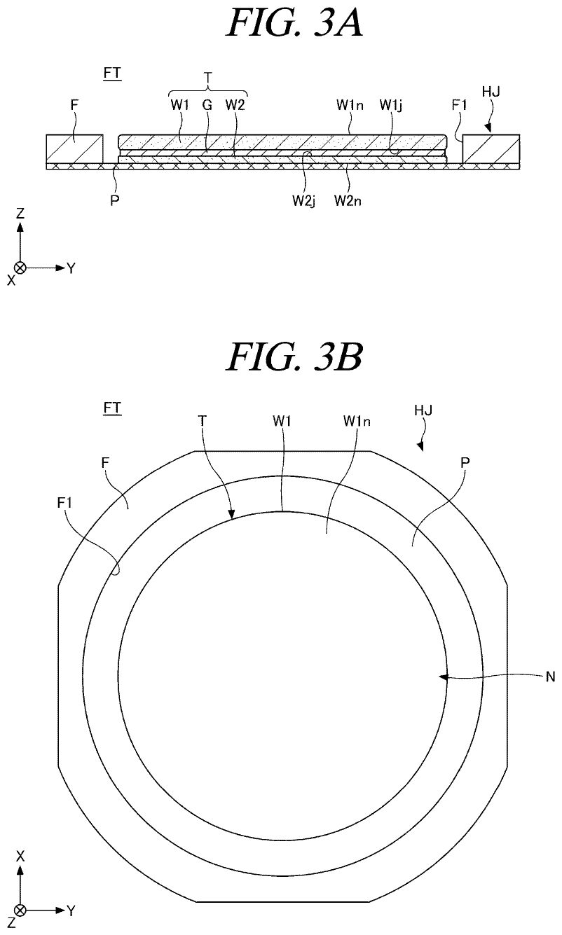

As shown in FIG. 3A and FIG. 3B, the first substrate W1 and the second substrate W2 constituting the combined substrate T are formed into circular plates having substantially the same diameter. Hereinafter, as shown in FIG. 3A, the first substrate W1 may sometimes be referred to as “upper wafer W1”; the second substrate W2, “lower wafer W2”; and the combined substrate T, “combined wafer T”. Also, hereinafter, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”. Further, the combined wafer T, the upper wafer W1, and the lower wafer W2 may have a shape (e.g., a polygonal shape) other than a circular shape, when viewed from the top.

At least one of the upper wafer W1 and the lower wafer W2 is a substrate on which electronic circuits or semiconductor devices are formed on a semiconductor substrate, such as a silicon wafer or a compound semiconductor wafer. The compound semiconductor wafer may be, for example, a GaAs wafer, a SiC wafer, a GaN wafer, or an InP wafer. One of the upper wafer W1 and the lower wafer W2 may be a bare wafer on which no electronic circuit or semiconductor device is formed.

FIG. 3A shows an example of the combined wafer T where a support substrate is applied as the upper wafer W1 and a silicon wafer on which electronic circuits or semiconductor devices are formed is applied as the lower wafer W2. In this case, the support substrate (the upper wafer W1) is thicker than the lower wafer W2. A material of the support substrate (the upper wafer W1) is not particularly limited, and may be silicon or quartz glass.

The bonding surface W1j of the upper wafer W1 is bonded to the bonding surface W2j of the lower wafer W2 by an adhesive G. The type of the adhesive G is not particularly limited, and an appropriate resin material may be selected depending on a material of the upper wafer W1 and a material of the lower wafer W2. Alternatively, the upper wafer W1 and the lower wafer W2 may be chemically bonded to each other. For example, the surfaces (the bonding surfaces W1j and W2j) of the upper wafer W1 and the lower wafer W2 are plasma-processed to be modified, and the modified surfaces are hydrophilized with pure water, and, thus, the surfaces are bonded to each other by a Van der Waals force and a hydrogen bond (intermolecular force).

Also, as shown in FIG. 3B, the combined wafer T has a notch N in a part of an outer edge in a circumferential direction. For example, the notch N is formed by cutting off each of outer edges of the upper wafer W1 and the lower wafer W2. The upper wafer W1 and the lower wafer W2 are bonded to each other such that the notch N of the upper wafer W1 is aligned with the notch N of the lower wafer W2.

As shown in FIG. 3A and FIG. 3B, the combined wafer T according to exemplary embodiments is held by a holding jig HJ equipped with a dicing frame F disposed around the combined wafer T and a dicing tape P. The dicing frame F of the holding jig HJ is an annular frame including an inner opening F1 having a greater diameter than the combined wafer T. The dicing frame F according to exemplary embodiments is formed into a substantially polygonal shape having circular arcs at a plurality of positions along its circumferential direction when viewed from the top. Also, the shape of the dicing frame F is not limited thereto, and may be an annular shape or the like. The thickness of the dicing frame F is set to be greater than that of the combined wafer T.

The dicing tape P of the holding jig HJ is formed of an elastically deformable resin material with flexibility, and has an adhesive layer on its one surface (upper surface). An outer peripheral portion of the dicing tape P is bonded to a rear surface of the dicing frame F, and, thus, the opening F1 of the dicing frame F is closed by the dicing tape P. Further, in the opening F1 of the dicing frame F, a rear surface of the combined wafer T is fixed to the one surface of the dicing tape P. More specifically, the non-bonding surface W2n of the lower wafer W2 is attached to the adhesive layer on the upper surface of the dicing tape P. With the dicing tape P, the combined wafer T is displaceable relative to the dicing frame F in a thickness direction, and a side circumferential surface of the combined wafer T can be exposed during a separation processing. In the following descriptions, the combined wafer T held by the holding jig HJ may also be referred to as “frame-attached combined wafer FT (frame-attached combined substrate)”.

Referring back to FIG. 1, the separation system 100 includes a carry-in/out station 1 and a processing station 2. The carry-in/out station 1 and the processing station 2 are configured as units separable from each other and arranged in this order along the positive X-axis direction.

The carry-in/out station 1 performs carry-in of the frame-attached combined wafer FT and carry-out of the separated upper wafer W1 and the separated lower wafer W2. Also, the holding jig HJ is attached to the separated lower wafer W2. In the following descriptions, the lower wafer W2 having the holding jig HJ attached thereto (integrated therewith) may also be referred to as “frame-attached wafer FW (frame-attached substrate)”.

The carry-in/out station 1 includes a placing section 11 configured to place a cassette, and a first transfer device 12 configured to transfer the frame-attached combined wafer FT, the separated upper wafer W1, and the separated frame-attached wafer FW (lower wafer W2).

The placing section 11 is equipped with a plurality of (four in FIG. 1) ports in which cassettes such as Front-Opening Unified Pods (FOUPs) are set. In each of a plurality of cassettes disposed in the respective ports, the frame-attached combined wafer FT, the upper wafer W1, and the frame-attached wafer FW are accommodated in a standby state. In other words, the ports constitute standby positions of the frame-attached combined wafer FT, the upper wafer W1, and the frame-attached wafer FW. The plurality of cassettes may include, for example, a cassette Ct (first container) that accommodates the frame-attached combined wafer FT, a cassette Cf (second container) that can accommodate the separated frame-attached wafer FW, and cassettes C1 and C2 (third containers) that can accommodate the separated upper wafer W1.

The first transfer device 12 is provided adjacent to a positive side in the X-axis direction of the placing section 11. The first transfer device 12 is equipped with a movement mechanism 121 (i.e., mover) and a plurality of (two in FIG. 1) transfer arms 122 mounted on the movement mechanism 121. The movement mechanism 121 enables each transfer arm 122 to be movable in a horizontal direction, movable up and down in a vertical direction, and pivotable around a vertical axis and may include a motor or the like, as known in the art. The movement mechanism 121 is movable in parallel to a direction in which the cassettes Ct, Cf, C1 and C2 are arranged. Each of the two transfer arms 122 includes a plurality of arms, and adjusts the horizontal position (position in the X-Y plane) of an end effector 123 provided at the distal end by performing operations, such as rotation, bending and extension/contraction, of each arm.

Meanwhile, the processing station 2 includes a buffer section 21, a second transfer device 22, a pre-processing device 23, a separation device 24, a lower wafer cleaning device 25 (frame-attached substrate cleaning device), and an upper wafer cleaning device 26 (substrate cleaning device). The buffer section 21 and the second transfer device 22 are provided between the pre-processing device 23 and the separation device 24 and the lower wafer cleaning device 25 and the upper wafer cleaning device 26 in the Y-axis direction of the separation system 100.

More specifically, the buffer section 21 is provided at an intermediate position in the Y-axis direction and on a negative side in the X-axis direction of the processing station 2. The second transfer device 22 is provided adjacent to the positive side in the X-axis direction of the buffer section 21. The pre-processing device 23 and the separation device 24 are arranged along the X-axis direction on the negative side in the Y-axis direction of the processing station 2. For example, the pre-processing device 23 is provided on the positive side in the X-axis direction, and the separation device 24 is provided on the negative side in the X-axis direction. The lower wafer cleaning device 25 and the upper wafer cleaning device 26 are arranged along the X-axis direction on a positive side in the Y-axis direction of the processing station 2. For example, the lower wafer cleaning device 25 is provided on the negative side in the X-axis direction, and the upper wafer cleaning device 26 is provided on the positive side in the X-axis direction.

The buffer section 21 forms a structure configured to deliver the unseparated frame-attached combined wafer FT, the separated upper wafer W1, and the separated frame-attached wafer FW (lower wafer W2) between the first transfer device 12 and the second transfer device 22. As shown in FIG. 2, the buffer section 21 includes, for example, a first wafer delivery module 21a, a second wafer delivery module 21b, an inverting mechanism-attached delivery module 21c, and an aligner 21d. The first wafer delivery module 21a, the second wafer delivery module 21b, the inverting mechanism-attached delivery module 21c, and the aligner 21d are stacked in this order along the downward vertical direction (negative Z-axis direction). However, the stacking order of the modules in the buffer section 21 is not limited thereto, and may be designed as required.

In the first wafer delivery module 21a, the frame-attached combined wafer FT carried from the carry-in/out station 1 is disposed. The frame-attached combined wafer FT disposed in the first wafer delivery module 21a is taken out by the second transfer device 22 and transferred into the processing station 2 (the pre-processing device 23 and the like).

In the second wafer delivery module 21b, the separated and cleaned frame-attached wafer FW is disposed. The frame-attached wafer FW disposed in the second wafer delivery module 21b is taken out by the first transfer device 12 and transferred into the cassette Cf of the placing section 11 of the carry-in/out station 1.

In the inverting mechanism-attached delivery module 21c, the separated upper wafer W1 is disposed. The inverting mechanism-attached delivery module 21c is equipped with an inverting mechanism configured to invert a front surface and a rear surface of the separated upper wafer W1. The front surface and the rear surface of separated upper wafer W1 disposed in the inverting mechanism-attached delivery module 21c is inverted by the inverting mechanism. Then, the upper wafer W1 is taken out by the second transfer device 22 and transferred to the upper wafer cleaning device 26 in the processing station 2.

The aligner 21d performs alignment of some or all of the frame-attached combined wafer FT, the separated upper wafer W1, and the separated frame-attached wafer FW. For example, when the aligner 21d performs the alignment of the frame-attached combined wafer FT, the aligner 21d calculates an eccentric amount of the combined wafer T by rotating the frame-attached combined wafer FT held on a placing table and detecting an outer periphery of the combined wafer T and a position of the notch N. The separation system 100 operates the aligner 21d and the first transfer device 12 or the second transfer device 22 based on the calculated eccentric amount, and adjusts a horizontal posture of the combined wafer T. This is the same for alignment of the upper wafer W1 or the frame-attached wafer FW (lower wafer W2).

Referring back to FIG. 1, the second transfer device 22 transfers the frame-attached combined wafer FT, the separated upper wafer W1, and the separated frame-attached wafer FW among the buffer section 21, the pre-processing device 23, the separation device 24, the lower wafer cleaning device 25, and the upper wafer cleaning device 26. The second transfer device 22 is equipped with a movement mechanism 221 and a plurality of (two in FIG. 1) transfer arms 222. The movement mechanism 221 enables each transfer arm 222 to be movable in the horizontal direction, movable up and down in the vertical direction, and pivotable around a vertical axis. Each of the two transfer arms 222 includes a plurality of arms, and adjusts the horizontal positions (position in the X-Y plane) of end effectors 223 and 224 provided at the distal ends by performing operations, such as rotation, bending and extension/contraction, of each arm.

### <Pre-Processing Device 23>

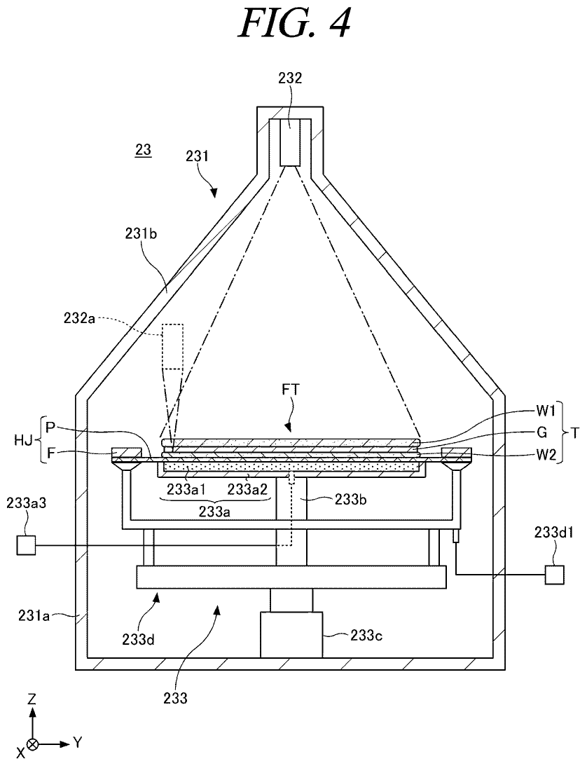

Further, the pre-processing device 23 of the processing station 2 is a processing device configured to reduce a bonding strength between the upper wafer W1 and the lower wafer W2 of the combined wafer T. Hereinafter, the pre-processing device 23 will be described with reference to FIG. 4.

The pre-processing device 23 is configured as a laser radiation device to radiate infrared light to the combined wafer T of the frame-attached combined wafer FT and reduce a bonding strength between the upper wafer W1 and the lower wafer W2. For example, the pre-processing device 23 includes a processing chamber 231 that accommodates the frame-attached combined wafer FT, a radiator 232 that radiates a laser inside the processing chamber 231, and a holder 233 that holds the frame-attached combined wafer FT inside the processing chamber 231.

The processing chamber 231 is formed into a tubular shape by vertically connecting a lower cylindrical member 231a and an upper conical member 231b, and forms an internal processing space in which the combined wafer T is pre-processed. The processing chamber 231 includes an opening (not shown) that allows carry-in and carry-out of the frame-attached combined wafer FT, and also includes a gate valve (not shown) capable of opening and closing the opening. The processing space of the processing chamber 231 is hermetically sealed when the gate valve is closed.

The lower cylindrical member 231a is internally equipped with the holder 233 to attract and hold the frame-attached combined wafer FT. The holder 233 includes a disk-shaped lower chuck 233a, a column 233b supports the lower chuck 233a, a rotary elevation mechanism 233c configured to rotate and elevate the lower chuck 233a, and a frame holder 233d configured to hold the dicing frame F.

The lower chuck 233a fixes the combined wafer T by attracting the dicing tape P of the holding jig HJ that holds the combined wafer T. The lower chuck 233a includes an attraction body 233a1 and a concave receptacle 233a2 that accommodates the attraction body 233a1. Also, the lower chuck 233a is internally equipped with a plurality of lift pins (not shown), and places the combined wafer T on the lower chuck 233a by elevating the lift pins.

The attraction body 233a1 is formed into a disk shape with an appropriate thickness and has a circular attraction surface on its upper surface to hold the combined wafer T via the dicing tape P. The attraction body 233a1 is a porous member formed of a resin material such as PCTFE (polychlorotrifluoroethylene). In other words, the lower chuck 233a is a porous chuck that applies an attraction pressure through its porosity. The attraction surface of the attraction body 233a1 has a flat shape without any machined grooves or holes.

The receptacle 233a2 is formed into a concave shape with a bottom wall and a side wall, and accommodates therein the attraction body 233a1. A suction path connected to a suction device 233a3, such as a vacuum pump, provided outside the processing chamber 231 is connected to the bottom wall of the receptacle 233a2. The suction device 233a3 is configured to apply an attraction pressure to the attraction body 233a1 through the suction path and the receptacle 233a2.

Also, the rotary elevation mechanism 233c is connected to a control device 9, and enables the lower chuck 233a to be rotatable and movable in the vertical direction under the control of the control device 9. For example, the rotary elevation mechanism 233c is internally equipped with a drive source for rotating the column 233b, a drive source for elevating the column 233b, and a transmission mechanism for transmitting a driving force of each drive source (all not shown). The functionality of the elements disclosed herein may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The frame holder 233d is equipped with a plurality of attraction pads and a plurality of support members that supports the respective attraction pads, and attracts and holds the dicing frame F (dicing tape P). Each attraction pad of the frame holder 233d is connected to a suction device 233d1, such as a vacuum pump, via a suction path. The suction device 233d1 is configured to apply an attraction pressure to each attraction pad under the control of the control device 9. Further, the support members of the frame holder 233d are connected to a rotation shaft (not shown) of the rotary elevation mechanism 233c. Accordingly, the holder 233 can integrally displace (rotate and elevate) both the combined wafer T held by the lower chuck 233a and the dicing frame F held by the frame holder 233d by the rotary elevation mechanism 233c.

Meanwhile, the upper conical member 231b of the processing chamber 231 forms an optical path of an infrared laser radiated by the radiator 232. It is preferable that an inner peripheral surface of the upper conical member 231b be processed to suppress diffused reflection of the infrared laser.

The radiator 232 is a laser source that radiates the infrared laser to the combined wafer T of the frame-attached combined wafer FT held by the holder 233. The radiator 232 may use a carbon dioxide (CO₂) gas laser, which uses a carbon dioxide gas as a medium, to obtain a continuous wave in an infrared region. For example, the radiator 232 has a radiation range for radiating the infrared laser to the entire surface of the combined wafer T. The infrared laser radiated from the radiator 232 passes through the upper wafer W1 to be absorbed by the adhesive G, and, thus, a gas is generated in the adhesive G. Accordingly, the infrared laser creates voids (cavities) in the adhesive G, which can reduce a bonding strength of the adhesive G. Further, during radiation of the infrared laser, the pre-processing device 23 may rotate the combined wafer T via the holder 233.

It is preferable that a wavelength of the infrared laser be set to an optimal value depending on the type of adhesive G used in the combined wafer T. For example, in the exemplary embodiments, the wavelength of the infrared laser is set to 9.3 μm.

Furthermore, the bonding strength of the adhesive G in the combined wafer T tends to be higher near an outer peripheral portion of the combined wafer T. Therefore, the radiator 232 is not limited to a configuration in which the infrared laser is radiated to the entire surface of the combined wafer T, and may also be configured to radiate the infrared laser to the outer peripheral portion of the combined wafer T. For example, as indicated by the dotted line in FIG. 4, the pre-processing device 23 may be configured to rotate the combined wafer T via the holder 233 by placing the radiator 232a at a position facing the outer peripheral portion and radiating the infrared laser from the radiator 232a. Accordingly, it becomes possible to reduce the bonding strength of the adhesive G along the entire circumference of the outer peripheral portion of the combined wafer T.

### <Separation Device 24>

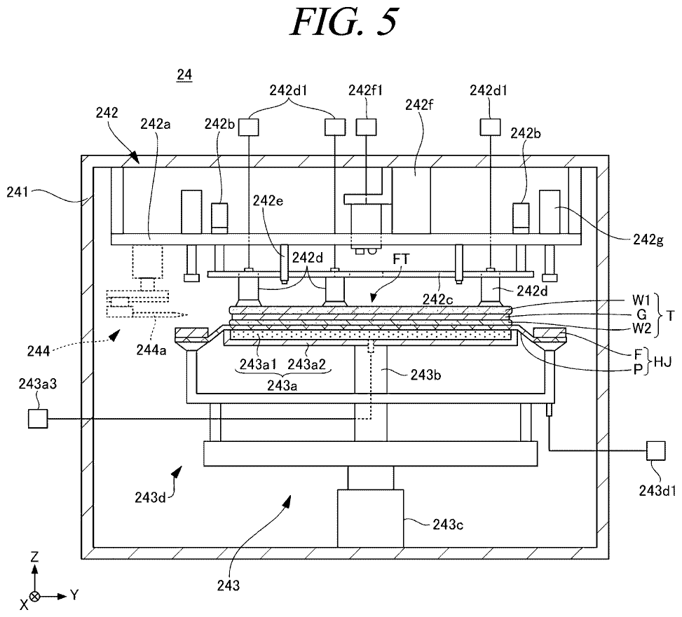

The separation device 24 of the processing station 2 is a processing device configured to perform a separation processing to actually separate the substrates (the upper wafer W1 and the lower wafer W2) of the combined wafer T that has been pre-processed by the pre-processing device 23. Hereinafter, the separation device 24 will be described with reference to FIG. 5.

The separation device 24 is equipped with a processing chamber 241 into which the combined wafer T is transferred, and includes an attraction separation device 242 and a lower holder 243 within the processing chamber 241.

The attraction separation device 242 is configured to attract the non-bonding surface W1n of the upper wafer W1 of the combined wafer T to hold the upper wafer W1, and configured to perform a separation processing to pull the upper wafer W1 upwards in the vertical direction. The attraction separation device 242 includes a base member 242a, two elevation mechanisms 242b provided on the base member 242a, a support member 242c supported by the two elevation mechanisms 242b, and a plurality of attraction devices 242d supported by the support member 242c to attract the upper wafer W1. Also, the attraction separation device 242 is equipped with a delivery holder 242f configured to deliver the separated upper wafer W1 to the second transfer device 22, and a pressing member 242g configured to press the dicing frame F of the holding jig HJ.

For example, the base member 242a is directly or indirectly fixed to a ceiling wall (or side wall) of the processing chamber 241. The base member 242a has sufficient rigidity and maintains a posture extending in the horizontal direction (X-Y axis direction) within the processing chamber 241.

The pair of (two) elevation mechanisms 242b are arranged in the Y-axis direction of the base member 242a and fixed at the same height relative to each other. The pair of elevation mechanisms 242b support both ends of the support member 242c in the Y-axis direction, and the support member 242c is located below the base member 242a in the vertical direction. Each elevation mechanism 242b includes a main body, a shaft, a load cell, and the like (all not shown), and is connected to the control device 9. Each elevation mechanism 242b independently displaces the support member 242c, which is connected to a lower end of the shaft, by elevating the shaft with a drive source and a transmission mechanism provided in the main body. The load cell detects a load applied to the shaft and transmits the detection result to the control device 9.

The support member 242c is a disk-shaped member that supports each attraction device 242d configured to attract the upper wafer W1. The support member 242c is formed of a metallic material or the like, and has sufficient rigidity to support each attraction device 242d and sufficient flexibility to be elastically deformed in the vertical direction. The support member 242c is suspended to bridge the pair of elevation mechanisms 242b and thus extends in substantially parallel to the lower holder 243. The support member 242c is elastically deformed in a curved manner along the Y-axis direction by independently elevating the pair of elevation mechanisms 242b to displace the supported attraction devices 242d. Also, the support member 242c includes a through-hole penetrating a central portion in its thickness direction. The through-hole allows the delivery holder 242f to pass therethrough.

Each attraction device 242d includes a tubular member extending in the vertical direction and a contact member provided at a lower end of the tubular member, and is connected to a suction device 242d1, such as a vacuum pump, via the suction path. The tubular member is securely connected to the support member 242c and protrudes from a lower surface of the support member 242c. The contact member comes into contact with the non-bonding surface W1n of the upper wafer W1. The suction device 242d1 is connected to the control device 9 and performs a suction operation under the control of the control device 9. Each attraction device 242d attracts the upper wafer W1 by applying an attraction pressure to the contact member from the suction device 242d1 while the contact member is in contact with the non-bonding surface Win of the upper wafer W1. For example, the attraction devices 242d are arranged to be distributed on the negative side in the Y-axis direction of the support member 242c, around the through-hole, and on the positive side in the Y-axis direction.

Also, the attraction separation device 242 includes a plurality of distance sensors 242e fixed to the base member 242a. By measuring the distance to the combined wafer T (upper wafer W1) facing each distance sensor 242e, the control device 9 can calculate the height (vertical position) of the upper wafer W1. For example, during the separation processing, the control device 9 calculates the height of the upper wafer W1 to recognize the progress of the separation.

The delivery holder 242f of the attraction separation device 242 is provided on the base member 242a, and attracts the non-bonding surface W1n of the separated upper wafer W1 held by each attraction device 242d to hold the upper wafer W1. The delivery holder 242f includes a base member, a plurality of attraction pads, a plurality of contact pads, and a base member elevation mechanism.

The base member of the delivery holder 242f extends in the vertical direction, supports each attraction pad and contact pad on its bottom surface, and moves up and down in the vertical direction via the base member elevation mechanism. The base member passes through the through-hole in the support member 242c when moving downwards. Each attraction pad is formed of a rubber material or the like and connected to a suction device 242f1, such as a vacuum pump, via the suction path. The suction device 242f1 is connected to the control device 9 and performs a suction operation under the control of the control device 9. The delivery holder 242f attracts the non-bonding surface W1n of the upper wafer W1 by generating an attraction pressure (negative pressure) in the plurality of attraction pads. Each contact pad is formed of a resin material into a hemispherical shape, and its protrusion amount from the base member can be adjusted by an adjustment unit (not shown). The contact pads come into contact with the non-bonding surface W1n of the upper wafer W1 attracted by the attraction pads and assist deviation of the upper wafer W1.

The base member elevation mechanism of the delivery holder 242f elevates the base member under the control of the control device 9. For example, the base member elevation mechanism displaces each attraction pad and each contact pad between a hold-switching position where the separated upper wafer W1 held by each attraction device 242d is attracted and a delivery position where the upper wafer W1 is delivered to the second transfer device 22.

Meanwhile, the pressing member 242g of the attraction separation device 242 is provided on an outer peripheral portion of the base member 242a (on a radially outer side of the pair of elevation mechanisms 242b), and presses the dicing frame F downwards at an appropriate timing. For example, four pressing members 242g are provided along the circumferential direction at positions corresponding to the dicing frame F transferred to the lower holder 243. The number of pressing members 242g is not particularly limited.

Each pressing member 242g includes a pressing pad, a shaft member, and a movement mechanism. The shaft member is equipped with the pressing pad at its lower end and moved up and down in the vertical direction by the movement mechanism. The movement mechanism is connected to the control device 9, elevates the shaft member under the control of the control device 9, and presses the dicing frame F by means of the pressing pad.

Also, the lower holder 243 of the separation device 24 is provided from an intermediate portion to a lower portion in the vertical direction of the processing chamber 241, and attracts and holds the frame-attached combined wafer FT. The lower holder 243 is configured substantially the same as the holder 233 of the pre-processing device 23. The lower holder 243 includes a disk-shaped lower chuck 243a, a column 243b configured to support the lower chuck 243a, a rotary elevation mechanism 243c configured to rotate and elevate the lower chuck 243a, and a frame holder 243d configured to hold the dicing frame F.

The lower chuck 243a fixes the combined wafer T by attracting the dicing tape P of the holding jig HJ that holds the combined wafer T. The lower chuck 243a includes an attraction body 243a1 and a concave receptacle 243a2 that accommodates the attraction body 243a1. Also, the lower chuck 243a is internally equipped with a plurality of lift pins (not shown), and places the combined wafer T on the lower chuck 243a by elevating each lift pin.

The attraction body 243a1 is formed into a disk shape with an appropriate thickness and has a circular attraction surface on its upper surface to hold the combined wafer T via the dicing tape P. The attraction body 243a1 is a porous member formed of a resin material such as PCTFE. The attraction surface of the attraction body 243a1 has a flat shape without any machined grooves or holes.

The receptacle 243a2 is formed into a concave shape with a bottom wall and a side wall, and accommodates therein the attraction body 243a1. A suction path connected to a suction device 243a3, such as a vacuum pump, provided outside the processing chamber 241 is connected to the bottom wall of the receptacle 243a2. The suction device 243a3 is configured to apply an attraction pressure to the attraction body 243a1 through the suction path and the receptacle 243a2.

Also, the rotary elevation mechanism 243c is connected to the control device 9, and enables the lower chuck 243a to be rotatable and movable in the vertical direction under the control of the control device 9. For example, the rotary elevation mechanism 243c is internally equipped with a drive source for rotating the column 243b, a drive source for elevating the column 243b, and a transmission mechanism for transmitting a driving force of each drive source (all not shown).

The frame holder 243d is equipped with a plurality of attraction pads and a plurality of support members that supports the respective attraction pads, and attracts and holds the dicing frame F. Each attraction pad of the frame holder 243d is connected to a suction device 243d1, such as a vacuum pump, via a suction path. The suction device 243d1 is configured to apply an attraction pressure to each attraction pad under the control of the control device 9. Further, the support members of the frame holder 243d are connected to a rotation shaft (not shown) of the rotary elevation mechanism 243c. Accordingly, the lower holder 243 can integrally move (rotate and elevate) both the combined wafer T held by the lower chuck 243a and the dicing frame F held by the frame holder 243d by the rotary elevation mechanism 243c.

Also, as indicated by the dotted line in FIG. 5, the separation device 24 may be equipped with a separation inducing device 244 configured to form a groove in the adhesive G of the combined wafer T. For example, the separation inducing device 244 includes a blade 244a, a blade sliding mechanism, and a blade elevation mechanism.

The blade 244a has a tip with an acute angle toward the positive Y-axis direction. The blade sliding mechanism supports the blade 244a so that the blade 244a protrudes in the positive Y-axis direction and reciprocates along the Y-axis direction based on driving of a non-illustrated drive source. The blade elevation mechanism is fixed, for example, to the base member 242a, and moves the blade sliding mechanism in the Z-axis direction based on driving of a non-illustrated drive source to adjust the height of the blade 244a.

The separation inducing device 244 adjusts the height of the blade 244a by using the blade elevation mechanism, and then, moves the blade 244a forward in the positive Y-axis direction by using the blade sliding mechanism. As the blade 244a moves forward, its tip enters the adhesive G between the upper wafer W1 and the lower wafer W2 from the side of the combined wafer T, and thus, forms the groove between the upper wafer W1 and the lower wafer W2. This groove breaks the adhesive G that bonds the outer periphery of the combined wafer T.

In the separation processing, the above-described separation device 24 attracts the upper wafer W1 of the combined wafer T by the attraction separation device 242 and attracts the lower wafer W2 (dicing tape P) of the combined wafer T by the lower holder 243. Then, the separation device 24 raises the elevation mechanisms 242b on the negative side in the Y-axis direction and thus raises each attraction device 242d on the negative side in the Y-axis direction. As a result, the upper wafer W1 is displaced to be lifted upwards relative to the lower wafer W2, which causes the separation between the upper wafer W1 and the lower wafer W2 from the negative Y-axis direction toward the positive Y-axis direction. Also, the separation device 24 lowers the delivery holder 242f to hold the separated upper wafer W1 via the attraction pads. Meanwhile, when the upper wafer W1 is separated, the lower holder 243 of the separation device 24 holds the frame-attached wafer FW in which the lower wafer W2 is attached to the dicing tape P of the holding jig HJ.

### <Lower Wafer Cleaning Device 25>

Referring back to FIG. 1, the lower wafer cleaning device 25 of the processing station 2 is a processing device (frame-attached substrate cleaning device) into which the separated frame-attached wafer FW is transferred by the second transfer device 22 and which performs cleaning on the bonding surface W2j, which is the separated surface of the lower wafer W2. The lower wafer cleaning device 25 may be configured appropriately depending on the cleaning method or the type of the adhesive G. For example, the lower wafer cleaning device 25 includes a processing chamber that accommodates the frame-attached wafer FW, a placement table that rotatably supports the frame-attached wafer FW inside the processing chamber, and a nozzle that discharges a cleaning liquid onto the separated surface (adhesive G) inside the processing chamber. Accordingly, the lower wafer cleaning device 25 can adequately remove the adhesive G from the separated surface of the lower wafer W2.

### <Upper Wafer Cleaning Device 26>

Further, the upper wafer cleaning device 26 of the processing station 2 is a processing device (substrate cleaning device) into which the separated upper wafer W1 is transferred by the second transfer device 22 and which performs cleaning on the bonding surface W1j, which is the separated surface of the upper wafer W1. Furthermore, the upper wafer W1, whose front surface and rear surface are inverted, is carried into the upper wafer cleaning device 26 via the inverting mechanism-attached delivery module 21c. The upper wafer cleaning device 26 may be configured substantially the same as the lower wafer cleaning device 25. Accordingly, the upper wafer cleaning device 26 can also adequately remove the adhesive G from the separated surface of the upper wafer W1.

### <Control Device 9>

The separation system 100 includes the control device 9 configured to control various operations of the above-described carry-in/out station 1 and processing station 2. The control device 9 is a computer having a processors 91, a memory 92, and an input/output interface (not shown). The processor 91 includes one or a combination of a central processing unit (CPU), a graphics processing unit (GPU), an application specific integrated circuit (ASIC), a field-programmable gate array (FPGA), and a circuit including a plurality of discrete semiconductors. The memory 92 includes a non-volatile memory and a volatile memory. The memory 92 stores therein a program for controlling various kinds of processings, and the processor 91 controls the operation of the separation system 100 by reading and executing the program stored in the memory 92. In other words, according to the present disclosure, the control device 9 is an electronic circuit equipped with CPU, GPU, ASIC, FPGA, etc., and performs various control operations described in the present disclosure by executing command codes stored in the memory 92 or by being designed as a circuit for special use.

### <Transfer Device of Separation System 100>

The separation system 100 configured as described above transfers the frame-attached combined wafer FT, the frame-attached wafer FW, and the upper wafer W1 by the first transfer device 12 of the carry-in/out station 1 and the second transfer device 22 of the processing station 2. Herein, the frame-attached combined wafer FT and the frame-attached wafer FW include the dicing frame F and thus have a large outer diameter. Meanwhile, the upper wafer W1 does not include the dicing frame F and thus has a smaller outer diameter than the frame-attached combined wafer FT and the frame-attached wafer FW. That is, the transfer devices transfer two types of transfer objects having different outer diameters.

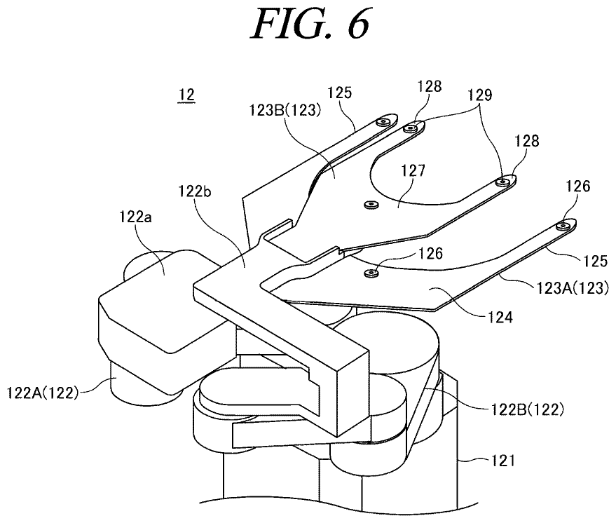

For this reason, the first transfer device 12 of the carry-in/out station 1 is equipped with a plurality of (two in the exemplary embodiment) different types of transfer arms 122. Hereinafter, a configuration of the first transfer device 12 will be described with reference to FIG. 6.

More specifically, the plurality of transfer arms 122 of the first transfer device 12 are mounted on the movement mechanism 121. The plurality of the transfer arms 122 includes a transfer arm 122A configured to transfer the frame-attached combined wafer FT and the frame-attached wafer FW, and a transfer arm 122B configured to transfer the upper wafer W1.

The transfer arm 122A includes a first end effector 123A having a plurality of arms and supporting both the frame-attached combined wafer FT and the frame-attached wafer FW. The first end effector 123A is mounted on a distal arm 122a located at the farthest end from the movement mechanism 121 among the plurality of arms. The distal arm 122a is internally equipped with a reciprocating mechanism (not shown) that moves the first end effector 123A back and forth along its central axis (longitudinal direction).

The first end effector 123A includes a base member 124 that is fixed to the distal arm 122a, and a pair of forks 125 that protrude in a distal end direction from the base member 124. Accordingly, the first end effector 123A has a U-shape when viewed from the top and includes an opening in the distal end direction. The base member 124 and the pair of forks 125 are formed from a single plate and are integrally continuous with each other. The base member 124 and each fork 125 of the first end effector 123A are formed corresponding in diameter to the dicing frame F and configured to transfer the dicing frame F.

Also, the first end effector 123A is equipped with a plurality of (four) attraction pads 126 on its upper surface. The attraction pads 126 are arranged near the opening on the distal end side of the base member 124 and at the tips of the respective forks 125 to face the circumferential direction of the dicing frame F. The attraction pads 126 communicate with a flow path provided within the first end effector 123A, and the flow path is connected to a suction device (not shown). The suction device is configured to apply an attraction pressure to each attraction pad 126 under the control of the control device 9 to attract the dicing frame F (dicing tape P) disposed on each attraction pad 126.

Meanwhile, the transfer arm 122B includes a second end effector 123B having a plurality of arms and supporting the upper wafer W1. The second end effector 123B is mounted on a distal arm 122b located at the farthest end from the movement mechanism 121 among the plurality of arms. The distal arm 122b is internally equipped with a reciprocating mechanism (not shown) that moves the second end effector 123B back and forth along its central axis (longitudinal direction).

The second end effector 123B includes a base member 127 that is fixed to the distal arm 122b, and a pair of forks 128 that protrude in a distal end direction from the base member 127. Accordingly, the second end effector 123B has a U-shape when viewed from the top and includes an opening in the distal end direction. The base member 127 and the pair of forks 128 are formed from a single plate and are integrally continuous with each other. The base member 127 and each fork 128 of the second end effector 123B are formed corresponding in diameter to the upper wafer W1 and configured to transfer the upper wafer W1. That is, the second end effector 123B has a smaller size than the first end effector 123A.

Also, the second end effector 123B is equipped with a plurality of (three) attraction pads 129 on its upper surface. The attraction pads 129 are arranged near the opening on the distal end side of the base member 127 and at the distal ends of the respective forks 128 to face an outer peripheral portion of the upper wafer W1. The attraction pads 126 communicate with a flow path provided within the second end effector 123B, and the flow path is connected to a suction device (not shown). The suction device is configured to apply an attraction pressure to each attraction pad 129 under the control of the control device 9 to attract the upper wafer W1 disposed on each attraction pad 129.

Meanwhile, as shown in FIG. 1, the second transfer device 22 of the processing station 2 transfers a transfer object among the buffer section 21, the pre-processing device 23, the separation device 24, the lower wafer cleaning device 25, and the upper wafer cleaning device 26. Therefore, it is required to improve the transfer efficiency of the second transfer device 22. In a configuration equipped with two different types of transfer arms 122 (the first end effector 123A and the second end effector 123B) like the first transfer device 12, the transfer efficiency may not be sufficiently improved. For example, if the second transfer device is equipped with two different types of transfer arms, it becomes difficult to perform operations, such as carrying the frame-attached wafer FW into the second wafer delivery module 21b and carrying the frame-attached combined wafer FT out of the first wafer delivery module 21a, in one access to the buffer section 21.

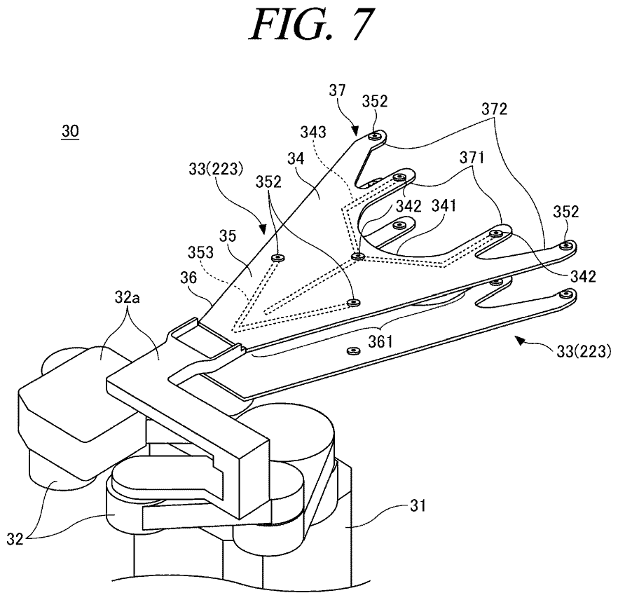

Therefore, in the separation system 100 according to the exemplary embodiment as shown in FIG. 1 and FIG. 7, a transfer device 30 capable of supporting both the frame-attached combined wafer FT (or the frame-attached wafer FW) and the upper wafer W1 is applied to the second transfer device 22 to improve the transfer efficiency. More specifically, the transfer device 30 is equipped with a movement mechanism 31 (the movement mechanism 221 of the second transfer device 22) and two transfer arms 32 (the transfer arms 222 of the second transfer device 22).

Further, each of the two transfer arms 32 is equipped with an end effector 33 (the end effector 223 of the second transfer device 22) capable of supporting both the frame-attached combined wafer FT (or the frame-attached wafer FW) and the upper wafer W1. The end effectors 33 of the respective transfer arms 32 are provided to be arranged in the vertical direction (up and down) in a standby state. The transfer device 30 can place the end effectors 33 at respective target positions (horizontal positions on the X-Y plane) by independently moving the transfer arms 32.

Each end effector 33 includes a first support 34 capable of supporting the circular upper wafer W1 from below, and a second support 35 capable of supporting the dicing frame F from below. Both the first support 34 and the second support 35 are formed from a single plate 36. However, the first support 34 and the second support 35 are continuous with each other in the single plate 36 and are not clearly demarcated. The first support 34 is located in a region of the plate 36 that faces a circular shape of the upper wafer W1 to be supported, and the second support 35 is located in a region of the plate 36 that faces an annular shape of the dicing frame F. Thus, the first support 34 is located in the inner side of the second support 35.

The plate 36 extends in a distal end direction from a distal arm 32a of the transfer arm 32 and also expands in a width direction. The plate 36 includes a wide base member 361 on a base end side and a plurality of (four in FIG. 4) forks 37 protruding in the distal end direction from the base member 361. Upper and lower surfaces of each fork 37 are integrally continuous with upper and lower surfaces of the base member 361.

The four forks 37 include a pair of first support forks 371 located on the inner side and constituting the first support 34, and a pair of second support forks 372 located on the outer side and constituting the second support 35. The pair of first support forks 371 protrude in parallel to each other. The first support 34 includes a U-shaped opening 341 formed by the pair of first support forks 371. The pair of second support forks 372 protrude away from each other, and a V-shaped space is formed between each second support fork 372 and its adjacent first support fork 371. Also, the pair of second support forks 372 protrude slightly further in the distal end direction than the pair of first support forks 371.

The first support 34 is defined to include the pair of first support forks 371 and a distal end region surrounding the U-shaped opening 341 of the base member 361. The first support 34 is equipped with first attraction pads 342 capable of supporting the upper wafer W1 at distal ends of the pair of first support forks 371 and in the distal end region of the base member 361. That is, three first attraction pads 342 are provided on the upper surface of the plate 36. Each first attraction pad 342 protrudes slightly from the upper surface of the plate 36 and the first attraction pads 342 support the upper wafer W1 at three points to be spaced from the plate 36. For example, the first attraction pads 342 are arranged to form the vertices of an equilateral triangle when viewed from the top.

Further, each first attraction pad 342 includes an attraction hole (not shown) in its central portion. The first support 34 is equipped with a flow path 343 that communicates with the attraction hole of each first attraction pad 342 and allows an attraction pressure to be applied to each first attraction pad 342. A suction device (not shown) is connected to the flow path 343 and is configured to apply an attraction pressure to each first attraction pad 342 under the control of the control device 9. Accordingly, the first support 34 can hold the upper wafer W1 placed on the first attraction pads 342.

The second support 35 is defined to include the pair of second support forks 372 and a region on a base end side rather than the distal end region of the base member 361. This second support 35 is equipped with second attraction pads 352 capable of supporting the dicing frame F at distal ends of the pair of second support forks 372 and in the region on the base end side of the base member 361. More specifically, one second attraction pad 352 is provided at a distal end of each second support fork 372, and two second attraction pads 352 are provided in a region on a base end side of the plate 36. Each second attraction pad 352 protrudes slightly from the upper surface of the plate 36 and supports the dicing frame F (the frame-attached combined wafer FT and the frame-attached wafer FW) at four points to be spaced from the plate 36. For example, the second attraction pads 352 are arranged to form the vertices of a trapezoid when viewed from the top.

Among the four second attraction pads 352, the two located in the base member 361 include attraction holes (not shown) in its central portion. The second support 35 is equipped with a flow path 353 that communicates with the attraction hole of each second attraction pad 352 and allows an attraction pressure to be applied to each second attraction pad 352. A suction device (not shown) is connected to the flow path 353 and is configured to apply an attraction pressure to each second attraction pad 352 under the control of the control device 9. Accordingly, the second support 35 can fix the dicing frame F placed on the second attraction pads 352. The flow path 353 can also communicate with the attraction holes of the second attraction pads 352 on the side of the pair of second support forks 372.

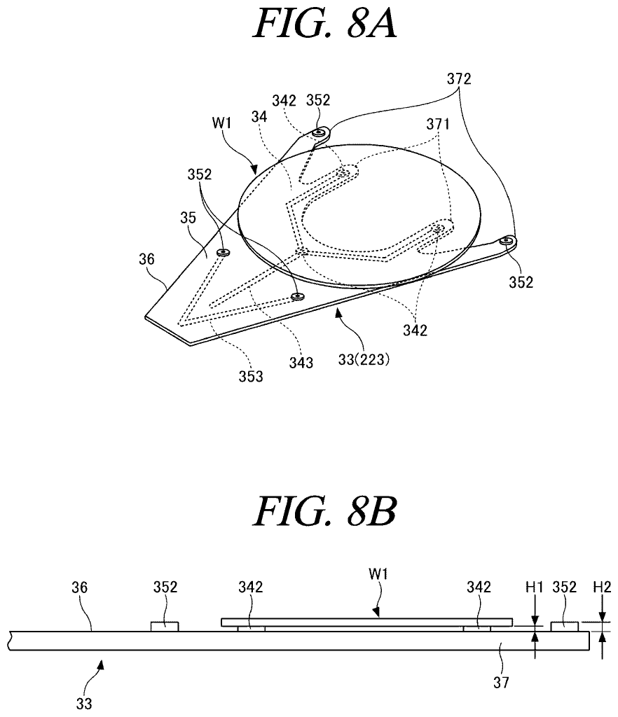

The transfer device 30 configured as described above may select a pattern of supporting the upper wafer W1 or a pattern of supporting the frame-attached combined wafer FT (or the frame-attached wafer FW) in the single end effector 33. More specifically, as shown in FIG. 8A, when supporting the upper wafer W1, the transfer device 30 moves the end effector 33 to below the upper wafer W1 under the control of the control device 9. Accordingly, the transfer device 30 can place the upper wafer W1 on the end effector 33 to cover the pair of first support forks 371 of the first support 34, the opening 341, and the distal end side of the base member 361.

When the transfer device 30 places the upper wafer W1, the first support 34 supports the outer peripheral portion of the upper wafer W1 at three points via the three first attraction pads 342. Further, the first support 34 can fix the upper wafer W1 by applying the attraction pressure of the suction device to each first attraction pad 342 through the flow path 343. In this state, the second attraction pads 352 provided in the region on the base end side of the base member 361 and in the pair of second support forks 372 are exposed to the outside of the upper wafer W1.

In the end effector 33 as shown in FIG. 8B, a height H1 of each first attraction pad 342 is set to be lower than a height H2 of each second attraction pad 352. Accordingly, the first support 34 can support the upper wafer W1 at a lower position than the frame-attached combined wafer FT to be described later and thus can stably hold the upper wafer W1.

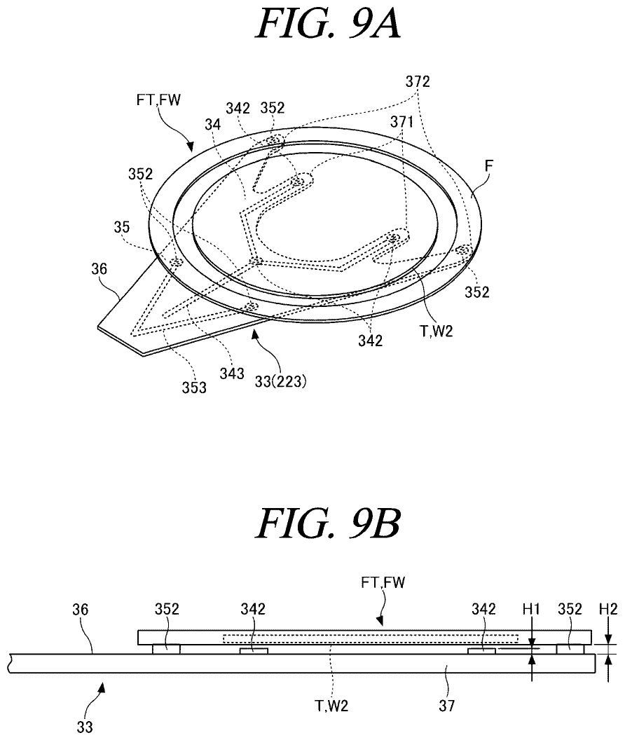

As shown in FIG. 9A, when supporting the frame-attached combined wafer FT, the transfer device 30 moves the single end effector 33 to below the frame-attached combined wafer FT under the control of the control device 9. Accordingly, the transfer device 30 can place the frame-attached combined wafer FT on the end effector 33 to cover the pair of second support forks 372 of the second support 35 as well as the distal end region and the region on the base end side of the base member 361. Similarly, the frame-attached wafer FW can be supported in the same manner as the frame-attached combined wafer FT.

When the transfer device 30 places the frame-attached combined wafer FT, the second support 35 supports the dicing frame F at four points via the four second attraction pads 352. Further, the second support 35 can fix the frame-attached combined wafer FT by applying the attraction pressure of the suction device to two second attraction pads 352 in the region on the base end side through the flow path 353. In this state, the first support 34 (the pair of first support forks 371, the distal end region of the base member 361, etc.) and the second support 35 are integrally covered.

Further, as shown in FIG. 9B, the second support 35 of the end effector 33 supports the frame-attached combined wafer FT at a higher position than the upper wafer W1. Accordingly, the end effector 33 can suppress interference of an inner portion of the frame-attached combined wafer FT with each first attraction pad 342 and thus can stably hold the frame-attached combined wafer FT.

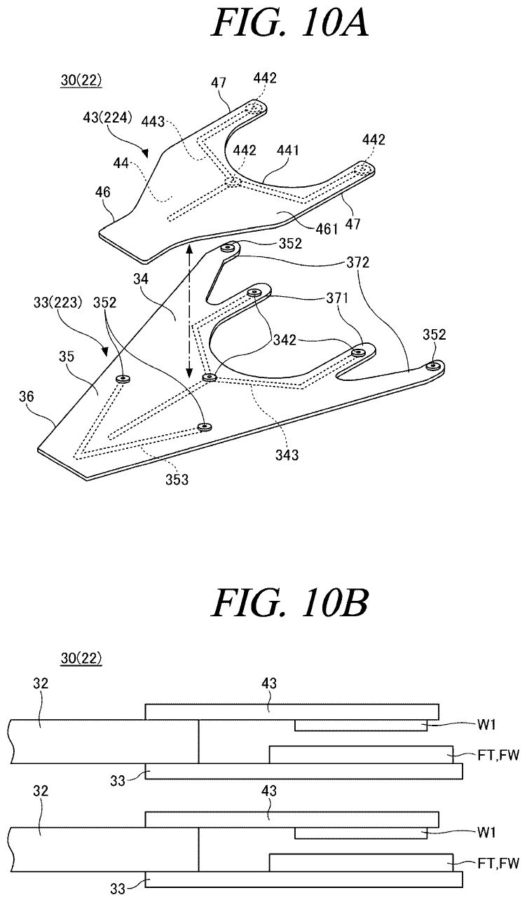

Furthermore, as shown in FIG. 10A and FIG. 10B, the second transfer device 22 is equipped not only with the above-described end effector 33 on each transfer arm 222, but also with a substrate end effector 43 capable of supporting an upper surface (the non-bonding surface W1n, opposite to the separated surface) of the upper wafer W1 without the dicing frame F. As shown in FIG. 10B, the substrate end effector 43 is fixed to the upper surface of the distal arm 32a and thus extends in non-contact with and in parallel to the end effector 33 fixed to the lower surface of the distal arm 32a.

Like the end effector 33, the substrate end effector 43 is formed by a single plate 46. The plate 46 includes a base member 461 and a pair of support forks 47 protruding in a distal end direction from the base member 461. Accordingly, the substrate end effector 43 has a U-shape when viewed from the top and includes an opening 441 in the distal end direction. The base member 461 and the pair of support forks 47 are integrally continuous with each other. The substrate end effector 43 is formed corresponding in diameter to the upper wafer W1.

Also, the substrate end effector 43 is equipped with a substrate support 44 on a lower surface of the plate 46, and the substrate support 44 attracts and holds the upper wafer W1. The substrate support 44 is equipped with a plurality of (three) attraction pads 442 on its lower surface. Each attraction pad 442 is arranged near the opening 441 on the distal end side of the base member 461 and at the distal ends of the respective support forks 47 to face the outer peripheral portion of the upper wafer W1. The attraction pads 442 communicate with a flow path 443 provided within the substrate end effector 43, and the flow path 443 is connected to a suction device (not shown). The suction device is configured to apply an attraction pressure to each attraction pad 442 under the control of the control device 9 to attract the upper wafer W1 from each attraction pad 442. Accordingly, the substrate end effector 43 can hold the upper wafer W1 on its lower surface.

The second transfer device 22 is equipped with the end effector 33 and the substrate end effector 43 on one transfer arm 32 (distal arm 32a) and also equipped with both the end effector 33 and the substrate end effector 43 on the other transfer arm 32 (distal arm 32a). Thus, according to a separation method to be described below, the second transfer device 22 can transfer the frame-attached combined wafer FT, the frame-attached wafer FW, and the upper wafer W1 in various ways within the processing station 2.

### <Separation Method>

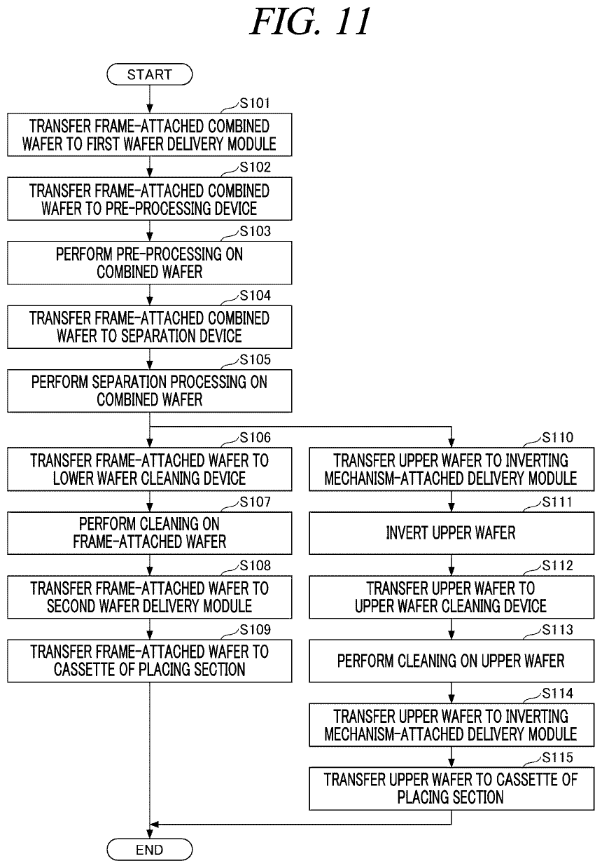

The separation system 100 is basically configured as described above. Hereinafter, the operation (the separation method including a transfer method) of the separation system 100 will be described with reference to the flowchart shown in FIG. 11.

In the separation method, the control device 9 performs processes S101 to S115 shown in FIG. 11 by controlling the components of the separation system 100.

In the separation method, the first transfer device 12 takes the frame-attached combined wafer FT out of the cassette Ct of the carry-in/out station 1 by the first end effector 123A and transfers the frame-attached combined wafer FT to the first wafer delivery module 21a (process S101: process (A)). The first end effector 123A attracts and holds the dicing frame F and thus stably transfers the frame-attached combined wafer FT (see FIG. 6).

Then, the second transfer device 22 carries the frame-attached combined wafer FT out of the first wafer delivery module 21a by the end effector 33 and transfers the frame-attached combined wafer FT to the pre-processing device 23 (process S102: process (B)). The end effector 33 attracts and holds the dicing frame F by the second support 35 and thus stably transfers the frame-attached combined wafer FT (see FIG. 9A and FIG. 9B).

Thereafter, the pre-processing device 23 performs the pre-processing to radiate the infrared laser to the adhesive G in the combined wafer T of the frame-attached combined wafer FT and reduce the bonding strength between the upper wafer W1 and the lower wafer W2 (process S103: process (B)).

After the pre-processing of the combined wafer T, the second transfer device 22 carries the frame-attached combined wafer FT out of the pre-processing device 23 by the end effector 33 and transfers the frame-attached combined wafer FT to the separation device 24 (process S104: process (B)).

The separation device 24 performs the separation processing to separate the combined wafer T of the frame-attached combined wafer FT into the upper wafer W1 and the lower wafer W2 (process S105: process (B)). Since the pre-processing to reduce the bonding strength of the combined wafer T is previously performed, the upper wafer W1 can be easily separated from the lower wafer W2 in the separation processing.

After the separation processing, the second transfer device 22 carries the separated frame-attached wafer FW (lower wafer W2) out of the separation device 24 by the end effector 33 and transfers the frame-attached wafer FW to the lower wafer cleaning device 25 (process S106). The end effector 33 attracts and holds the dicing frame F by the second support 35 and thus stably transfers the frame-attached wafer FW (see FIG. 9A and FIG. 9B).

The lower wafer cleaning device 25 performs the cleaning on the frame-attached wafer FW to remove the adhesive G remaining on the separated surface of the lower wafer W2 (process S107).

After the cleaning, the second transfer device 22 carries the frame-attached wafer FW out of the lower wafer cleaning device 25 by the end effector 33 and transfers the frame-attached wafer FW to the second wafer delivery module 21b (process S108: process (C)).

Then, in the carry-in/out station 1, the first transfer device 12 carries the frame-attached wafer FW out of the second wafer delivery module 21b by the first end effector 123A and transfers the frame-attached wafer FW to the cassette Cf of the placing section 11 (process S109: process (D)).

Further, the separation system 100 performs the carry-out and the cleaning of the upper wafer W1 separated by the separation device 24 in parallel with the transfer processing and the cleaning of the frame-attached wafer FW. More specifically, the second transfer device 22 carries the upper wafer W1 out of the separation device 24 by the substrate end effector 43 and transfers the upper wafer W1 to the inverting mechanism-attached delivery module 21c at different timing from the carry-out of the frame-attached wafer FW (process S110). That is, the substrate end effector 43 enters above the upper wafer W1, which has been separated by the separation device 24 and is being held by the delivery holder 242f, and attracts the upper surface of the upper wafer W1 by each attraction pad 442 on its lower surface. This is because the lower surface of the upper wafer W1 is the separated surface on which the adhesive G remains. The second transfer device 22 holds the upper surface (non-bonding surface W1n) of the upper wafer W1 and thus stably transfers the upper wafer W1.

The inverting mechanism-attached delivery module 21c inverts the front surface and the rear surface of the upper wafer W1 transferred by the second transfer device 22 (process S111).

Then, the second transfer device 22 holds the upper wafer W1, which has been inverted so that the separated surface is facing upwards, by the end effector 33 and transfers the upper wafer W1 from the inverting mechanism-attached delivery module 21c to the upper wafer cleaning device 26 (process S112). The end effector 33 attracts and holds the upper wafer W1 by the first support 34 and thus stably transfers the upper wafer W1 (see FIG. 9A and FIG. 9B).

The upper wafer cleaning device 26 performs the cleaning on the upper wafer W1 to remove the adhesive G remaining on the separated surface of the upper wafer W1 (process S113).

After the cleaning, the second transfer device 22 carries the upper wafer W1 out of the upper wafer cleaning device 26 by the end effector 33 and transfers the upper wafer W1 to the inverting mechanism-attached delivery module 21c (process S114: process (C)). The inverting mechanism-attached delivery module 21c does not invert the upper wafer W1 at the time of the carry-in of the upper wafer W1 in the second time.

Then, the first transfer device 12 carries the upper wafer W1 out of the inverting mechanism-attached delivery module 21c by the second end effector 123B and transfers the upper wafer W1 to the cassettes C1 or C2 of the placing section 11 (process S115: process (D)). The second end effector 123B attracts and holds the upper wafer W1 and thus stably transfers the upper wafer W1 (see FIG. 6).

Also, the separation system 100 sequentially performs the separation method on a plurality of frame-attached combined wafers FT according to the processing status of each device. For example, while the lower wafer W2 is cleaned by the lower wafer cleaning device 25 and the upper wafer W1 is cleaned by the upper wafer cleaning device 26, the separation system 100 may perform the separation processing on the next frame-attached combined wafer FT by the separation device 24. Further, while the separation device 24 performs the separation processing, the separation system 100 performs the pre-processing on the next frame-attached combined wafer FT by the pre-processing device 23. Furthermore, the separation system 100 can transfer a transfer object by the first transfer device 12 or the second transfer device 22 between the pre-processing, the separation processing, and the cleaning. Accordingly, the separation system 100 can efficiently separate the plurality of combined wafers T.

Moreover, in the transfer method of the transfer object, the first transfer device 12 and the second transfer device 22 may operate the two end effectors 33 independently to hold and transfer the frame-attached combined wafer FT, the frame-attached wafer FW, and the upper wafer W1 simultaneously. For example, while the first transfer device 12 transfers the frame-attached combined wafer FT or the frame-attached wafer FW by the first end effector 123A, it can transfer the upper wafer W1 by the second end effector 123B. Similarly, while the second transfer device 22 transfers the frame-attached combined wafer FT, the frame-attached wafer FW, or the upper wafer W1 by one end effector 33, it can transfer the frame-attached combined wafer FT, the frame-attached wafer FW, or the upper wafer W1 by the other end effector 33. Alternatively, the second transfer device 22 may transfer the frame-attached wafer FW by one end effector 33 and transfer the upper wafer W1 by one substrate end effector 43. That is, by applying the two end effectors 33 equipped with the first support 34 and the second support 35, the second transfer device 22 can transfer the transfer object in various ways, and, thus, it is possible to improve the transfer efficiency of the transfer object and also possible to improve the processing efficiency of the overall separation method.

Also, the separation system 100 and the transfer method according to the present disclosure are not limited to the above-described exemplary embodiment and may take various modification examples. For example, the separation system 100 according to the above-described exemplary embodiment has the configuration in which the first transfer device 12 is equipped with the first end effector 123A and the second end effector 123B. However, the present disclosure is not limited thereto. In the separation system 100, the transfer device 30 equipped with the end effector 33 may be applied to the first transfer device 12. Accordingly, even in the carry-in/out station 1, it becomes possible to adopt various transfer modes, such as simultaneously transferring the frame-attached combined wafer FT, the frame-attached wafer FW, or the upper wafer W1. In this case, the substrate end effector 43 may not be necessarily provided in the first transfer device 12. This is because it is not required to hold the upper wafer W1 from above.

Further, the pre-processing device 23 configured to reduce the bonding strength of the combined wafer T is not limited to the infrared laser radiation device, and other devices, such as an ultraviolet radiation device or a heat treatment device, can also be applied depending on the type of the adhesive G. The number of transfer arms of the first transfer device 12 or the second transfer device 22 is not limited to two, and may be three or more or may be one.

### First Modification Example

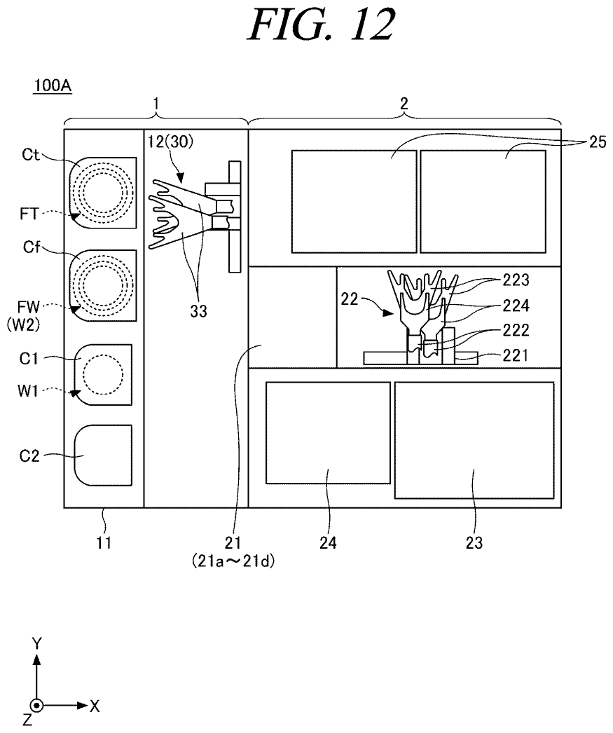

For example, the above-described separation system 100 is configured to include both the lower wafer cleaning device 25 and the upper wafer cleaning device 26. However, the separation system 100 may also be configured without one or both of these cleaning devices. For example, a separation system 100A according to a first modification example shown in FIG. 12 is configured to include the two lower wafer cleaning devices 25 without the upper wafer cleaning device 26. In this case, the upper wafer W1 is not subjected to the cleaning, but the front surface and the rear surface of the upper wafer W1 is inverted by the inverting mechanism-attached delivery module 21c and then transferred into cassettes C1 or C2. The upper wafer W1 may be subjected to the cleaning at a different location or be discarded.

Further, the separation system 100A according to the first modification example is an example in which the first transfer device 12 is equipped with the two end effectors 33 (see FIG. 7). Accordingly, the separation system 100A can increase the degree of freedom in transferring the frame-attached combined wafer FT, the frame-attached wafer FW, and the upper wafer W1 even in the carry-in/out station 1. Thus, it is possible to improve the transfer efficiency.

### Second Modification Example

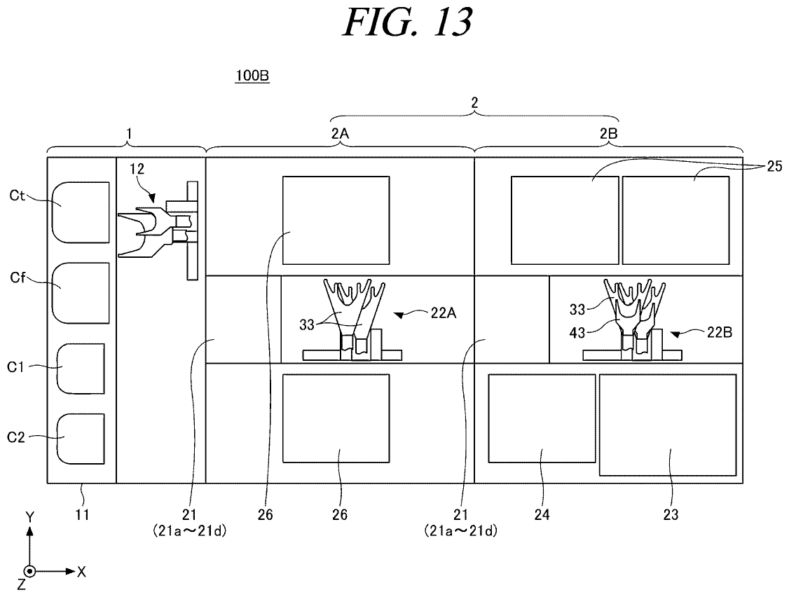

Furthermore, a separation system 100B according to a second modification example shown in FIG. 13 is configured to include a plurality of (two) processing stations 2, each equipped with the transfer device 30. More specifically, the processing stations 2 includes a first processing station 2A adjacent to the carry-in/out station 1 and a second processing station 2B adjacent to the first processing station 2A. The carry-in/out station 1, the first processing station 2A, and the second processing station 2B are arranged in this order along the positive X-axis direction.

The first processing station 2A is equipped with the buffer section 21 and a second transfer device 22A at an intermediate position in the Y-axis direction. Also, the first processing station 2A is equipped with a plurality of (two) upper wafer cleaning devices 26 on both sides in the Y-axis direction between the buffer section 21 and the second transfer device 22A.

In the first processing station 2A, the transfer device 30 equipped with the plurality of end effectors 33 (see FIG. 7) is applied to the second transfer device 22A. Further, the second transfer device 22A does not include the substrate end effector 43. This is because the upper wafer W1, which has been inverted by the inverting mechanism-attached delivery module 21c in the second processing station 2B to be described below, is transferred into the first processing station 2A.

Meanwhile, the second processing station 2B is equipped with the buffer section 21 and a third transfer device 22B at an intermediate position in the Y-axis direction. Also, the second processing station 2B is equipped with the pre-processing device 23 and the separation device 24 arranged on the negative side in the Y-axis direction and a plurality of (two) lower wafer cleaning devices 25 arranged on the positive side in the Y-axis direction.

In the second processing station 2B, the transfer device 30 equipped with the end effector 33 and the substrate end effector 43 (see FIG. 10A and FIG. 10B) is applied to the third transfer device 22B. Accordingly, the third transfer device 22B can transfer the frame-attached combined wafer FT and the frame-attached wafer FW by means of the end effector 33 and can also transfer the upper wafer W1 in a suspended state from the separation device 24 by means of the substrate end effector 43.

Even when the separation system 100B is equipped with a plurality of divided processing stations 2 to which the transfer devices 30 are applied respectively, it can adequately transfer the frame-attached combined wafer FT, the frame-attached wafer FW, and the upper wafer W1 and can perform the appropriate processing. Also, the separation system 100B is equipped with a plurality of cleaning devices (the lower wafer cleaning device 25 and the upper wafer cleaning device 26) and thus can distribute the upper wafer W1 and the frame-attached wafer FW across these devices during the cleaning, which tends to be time-consuming.

### Third Modification Example

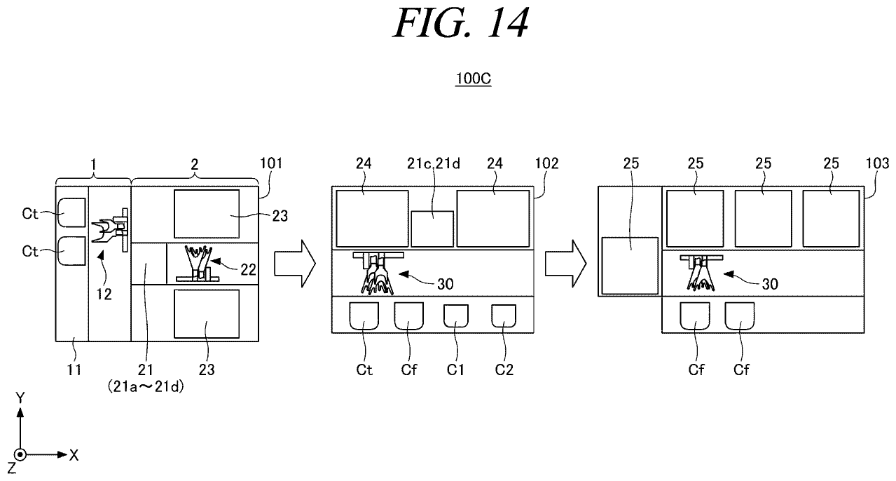

Moreover, a separation system 100C according to a third modification example shown in FIG. 14 is divided into three systems to perform the separation method of the combined wafer T. For example, the separation system 100C may include a first system 101 equipped with the pre-processing devices 23, a second system 102 equipped with the separation devices 24, and a third system 103 equipped with the lower wafer cleaning devices 25.

Like the separation system 100 according to the exemplary embodiment, the first system 101 is equipped with the carry-in/out station 1 including the first transfer device 12 and the processing station 2 including the second transfer device 22. The processing station 2 is equipped with the pre-processing devices 23 on both sides in the Y-axis direction to reduce the bonding strength of the combined wafer T in the frame-attached combined wafer FT. The second transfer device 22 transfers the frame-attached combined wafer FT between the buffer section 21 and each pre-processing device 23.

The second system 102 is equipped with the transfer device 30 including the end effector 33 and the substrate end effector 43 and is configured to directly transfer the frame-attached combined wafer FT to the separation devices 24. Further, the second system 102 is equipped with the inverting mechanism-attached delivery module 21c and the aligner 21d and functions to invert the upper wafer W1, which has been separated by each separation device 24. Accordingly, the transfer device 30 can adequately transfer the pre-processed frame-attached combined wafer FT, the separated frame-attached wafer FW, and the upper wafer W1 between the separation device 24, the inverting mechanism-attached delivery module 21c, the aligner 21d, and each of the cassettes Ct, Cf, C1 and C2.

Furthermore, the third system 103 is equipped with the transfer device 30 including the end effector 33 and is configured to directly transfer the separated frame-attached wafer FW to the lower wafer cleaning devices 25. Accordingly, the third system 103 can efficiently perform cleaning on the frame-attached wafer FW.

In the separation system 100C, each system is equipped with different devices. Thus, it is possible to improve the degree of freedom in layout and the applicability during factory setup by supplementing only a lacking system to the existing system.

As described above, according to the separation systems 100 and 100A to 100C and the separation method of the present disclosure, it is possible to promote the size reduction of the system by unifying the carry-in/out station for the frame-attached combined wafer FT, the frame-attached wafer FW, and the upper wafer W1. Also, the separation systems 100 and 100A to 100C are equipped with the first transfer device 12 in the carry-in/out station 1 and the second transfer device 22 in the processing station 2. Accordingly, the separation systems 100 and 100A to 100C can improve the transfer efficiency of the combined wafers T, the separated upper wafer W1, and the frame-attached wafer FW and thus can improve the production efficiency of the overall system. In particular, the processing station 2 is equipped with both the separation device 24 and the pre-processing device 23, and, thus, the separation of the combined wafer T can be adequately completed within the single system. Therefore, it is possible to further improve the production efficiency.

Further, in the carry-in/out station 1, the cassette Ct (first container) for accommodating the frame-attached combined wafer FT, the cassette Cf (second container) for accommodating the frame-attached wafer FW, and the cassettes C1 and C2 (third containers) for accommodating the upper wafer W1 are arranged. Accordingly, the first transfer device 12 in the carry-in/out station 1 can adequately perform the carry-in and the carry-out of the target object between the cassettes. In this case, the first transfer device 12 moves in parallel to the direction in which the cassettes Ct, Cf, C1 and C2 are arranged by the movement mechanism 121, which enables a smooth access to an appropriate cassette.

Furthermore, the processing station 2 is equipped with the lower wafer cleaning device 25 (frame-attached substrate cleaning device) and thus can adequately perform the cleaning on the separated lower wafer W2 (frame-attached wafer FW). Moreover, the separation system 100 is equipped with the inverting mechanism-attached delivery module 21c in the buffer section 21 and thus can invert the separated surface of the upper wafer W1, which is facing downwards, to face upwards and transfer the upper wafer W1. Also, the processing station 2 is equipped with the upper wafer cleaning device 26 (substrate cleaning device) and thus can adequately perform the cleaning on the separated upper wafer W1.

The second transfer device 22 is equipped with the transfer arms 222 capable of supporting the frame-attached combined wafer FT and the upper wafer W1, and thus can efficiently transfer these transfer objects. Further, the second transfer device 22 supports the surface opposite to the separated surface of the upper wafer W1 by the substrate end effector 43 and thus can carry the upper wafer W1 out of the separation device 24 without contact with the separated surface of the upper wafer W1.

The separation systems 100 and 100A to 100C and the separation method of the present disclosure are not limited to the above examples. The above-described exemplary embodiments can be modified and improved in various ways without departing from the scope and the spirit of claims. Unless contradictory, other configurations may be adopted, and the disclosures in the various exemplary embodiments can be combined appropriately.

According to embodiments of the present disclosure, it is possible to promote the size reduction of the system and improve the production efficiency.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A separation system, comprising:
a carry-in/out station for accommodating a combined substrate having a first substrate and a second substrate bonded together, and for accommodating the first substrate and the second substrate separated from one another; and
a processing station including at least one of:
a separation device for separating the combined substrate into the first substrate and the second substrate; and
a pre-processing device for reducing a bonding strength between the first substrate and the second substrate of the combined substrate,
wherein the carry-in/out station includes a first transfer device for transferring the combined substrate and the separated first substrate and the separated second substrate, and
the processing station includes a second transfer device for transferring the combined substrate, the separated first substrate and the separated second substrate.

2. The separation system of claim 1,
wherein with respect to a holding jig including a dicing frame provided with an opening and a dicing tape fixed to the dicing frame to close the opening, the combined substrate is formed as a frame-attached combined substrate attached to the dicing tape in the opening, and
the carry-in/out station includes a placing section for placing a first container that accommodates the frame-attached combined substrate, a second container that accommodates the separated first substrate, and a third container that accommodates the separated second substrate.

3. The separation system of claim 2,
wherein the first transfer device includes a mover to be moved in parallel to a direction in which the first container, the second container, and the third container are arranged.

4. The separation system of claim 2,
wherein the third container accommodates a frame-attached combined substrate in which the separated second substrate is attached to the holding jig.

5. The separation system of claim 4,
wherein the processing station further includes a frame-attached substrate cleaning device for cleaning a separated surface of the frame-attached combined substrate after being separated.

6. The separation system of claim 4,
wherein the first transfer device including a first end effector for transferring the frame-attached combined substrate or the separated frame-attached combined substrate, and a second end effector for transferring the separated first substrate.

7. The separation system of claim 2, further comprising:
a buffer section for delivering the frame-attached combined substrate, the separated first substrate, and the separated second substrate between the first transfer device and the second transfer device,
wherein the buffer section includes an inverter for inverting a front surface and a rear surface of the first substrate.

8. The separation system of claim 7,
wherein the processing station includes a substrate cleaning device for cleaning a separated surface of the separated first substrate which is inverted by the inverter.

9. The separation system of claim 2,
wherein the second transfer device includes multiple transfer arms for supporting the frame-attached combined substrate and the first substrate without the dicing frame.

10. The separation system of claim 2,
wherein the second transfer device includes a transfer arm for supporting a surface opposite to a separated surface of the first substrate without the dicing frame.

11. The separation system of claim 1,
wherein the processing station includes both the separation device and the pre-processing device.

12. A separation method of performing a processing to separate a combined substrate, in which a first substrate and a second substrate are bonded to each other, into the first substrate and the second substrate, comprising:
transferring the combined substrate, which stands by at a standby position in a carry-in/out station, into a processing station by a first transfer device;
performing separation processing, the separation processing being performed to transfer the combined substrate by a second transfer device and separate the combined substrate into the first substrate and the second substrate by a separation device provided in the processing station;
transferring the combined substrate, the first substrate or the second substrate, which is subjected to the separation processing, into the carry-in/out station by the second transfer device; and
transferring the combined substrate, the first substrate or the second substrate, which is transferred into the carry-in/out station by the second transfer device, to the standby position by the first transfer device.

13. The separation method of claim 12, further comprising:
transferring the combined substrate to a pre-processing device; and
reducing, by the pre-processing device, a bonding strength between the first substrate and the second substrate of the combined substrate.

14. The separation method of claim 13, wherein the pre-processing device includes one of an infrared laser radiation device, an ultraviolet radiation device and a heat treatment device.

15. The separation method of claim 13, further comprising:
after separation processing, transferring the first substrate to a first substrate cleaning device and transferring the second substrate to an inverter.

16. The separation method of claim 15, further comprising:
cleaning, by the first substrate cleaning device, the first substrate by removing adhesive remaining on a separated face of the first substrate;
inverting, by the inverter, the second substrate;
transferring the second substrate to second substrate cleaning device; and
cleaning, by the second substrate cleaning device, the second substrate by removing adhesive remaining on a separated face of the second substrate.

17. A separation system, comprising:
a carry-in/out station for accommodating a combined substrate having a first substrate and a second substrate bonded together and for accommodating the separated first substrate and the separated second substrate; and
a processing station including at least one of a separation device for separating the combined substrate into the first substrate and the second substrate,
wherein the carry-in/out station includes a first transfer device for transferring the combined substrate and the separated first substrate and the separated second substrate, and
the processing station includes a second transfer device for transferring the combined substrate, the separated first substrate and the separated second substrate.

18. The separation system of claim 17, wherein the processing system further includes a pre-processing device for performing radiation and/or heat treatment to reduce a bonding strength between the first substrate and the second substrate of the combined substrate.

19. The separation system of claim 18, wherein the carry-in/out station includes a placing section for placing a first container that accommodates the frame-attached combined substrate, a second container that accommodates the separated first substrate, and a third container that accommodates the separated second substrate.

20. The separation system of claim 19, wherein the first transfer device includes a first end effector for transferring the combined substrate and a second end effector for transferring the separated first substrate.
